(19) United States
(12) Patent Application Publication
(10) Pub. No.: US 2026/0276752 A1
(43) Pub. Date: Sep. 17, 2026

(54) MAGNETORESISTIVE ELEMENT AND MAGNETIC SENSOR

(71) Applicant: TDK Corporation, Tokyo (JP)

(72) Inventors: Hiroki OMURA, Tokyo (JP); Hirokazu TAKAHASHI, Tokyo (JP)

(73) Assignee: TDK Corporation, Tokyo (JP)

(21) Appl. No.: 19/560,159

(22) Filed: Mar. 9, 2026

(30) Foreign Application Priority Data
Mar. 11, 2025 (JP) 2025-038155

(51) Int. Cl. G01R 33/09

(52) U.S. Cl. CPC G01R 33/098; G01R 33/093

(57) ABSTRACT

An magnetoresistive element includes: a first magnetic layer; a second magnetic layer whose magnetization direction changes according to an external magnetic field; a spacer layer arranged between the first magnetic layer and the second magnetic layer; and an antiferromagnetic layer arranged on a side of the first magnetic layer opposite to the spacer layer, the first magnetic layer being magnetized to include a component in a perpendicular direction orthogonal to an in-plane direction, the first magnetic layer including a stack structure in which a stack of a first metal layer and a second metal layer stacked together is repeatedly stacked, a specific metal layer of the first metal layers being formed with a composition different from a composition of another metal layer that is not in contact with the antiferromagnetic layer.

### CROSS-REFERENCE TO RELATED APPLICATION

This application claims the benefit of Japanese Priority Patent Application No. 2025-038155 filed on Mar. 11, 2025, the entire contents of which are incorporated herein by reference.

### BACKGROUND

The disclosure relates to a magnetoresistive element including a magnetic layer magnetized to include a component in a perpendicular direction orthogonal to an in-plane direction, and a magnetic sensor including the magnetoresistive element.

A spin-valve magnetoresistive element includes a magnetization pinned layer, a free layer whose magnetization direction is variable according to the direction of an external magnetic field, and a spacer layer arranged between the magnetization pinned layer and the free layer.

JP 2012-519963 T, JP 2012-59807 A, and JP 2007-142364 A each disclose a magnetoresistive element including a magnetization pinned layer as a perpendicular magnetization film whose magnetization direction is fixed in a perpendicular direction, in the application of a magnetic memory. For example, control is performed to record information “0” when the magnetization directions of the free layer (referred to as a “recording layer” in JP 2012-59807 A, and JP 2007-142364 A) and the magnetization pinned layer are in a parallel state, while control is performed to record information “1” when the magnetization directions of the free layer and the magnetization pinned layer are in an antiparallel state.

In JP 2012-519963 T, JP 2012-59807 A, and JP 2007-142364 A, the layer structure of the entire magnetoresistive element including the free layer and the magnetization pinned layer is optimized to reduce write current density.

In an application where a magnetoresistive element having a magnetization pinned layer as a perpendicular magnetization film is used in a magnetic sensor, a change in magnitude of an external magnetic field in a perpendicular direction is recognized as a change in resistance, and a detection signal based on the change in resistance is output.

By stacking the magnetization pinned layer and an antiferromagnetic layer together and generating an exchange bias magnetic field between the magnetization pinned layer and the antiferromagnetic layer, the magnetization direction of the magnetization pinned layer can be fixed in either one direction of the perpendicular directions.

### SUMMARY

A magnetoresistive element according to one embodiment of the disclosure is a magnetoresistive element configured to have a resistance that changes according to an external magnetic field, and includes a first magnetic layer, a second magnetic layer whose magnetization direction changes according to the external magnetic field, a spacer layer arranged between the first magnetic layer and the second magnetic layer, and an antiferromagnetic layer arranged on a side of the first magnetic layer opposite to the spacer layer. The first magnetic layer is magnetized to include a component in a perpendicular direction orthogonal to an in-plane direction. The first magnetic layer includes a stack structure in which a stack of a first metal layer and a second metal layer stacked together is repeatedly stacked, and the first metal layer in each stack is arranged on a side closer to the antiferromagnetic layer than the second metal layer is. A specific metal layer of the first metal layers that is in contact with the antiferromagnetic layer is formed with a composition different from a composition of another metal layer that is not in contact with the antiferromagnetic layer.

A magnetic sensor according to an embodiment of the disclosure includes a magnetoresistive element and is configured to detect an external magnetic field including a component in a perpendicular direction. The magnetoresistive element is the magnetoresistive element disclosed herein.

Objects, features, and advantages of the disclosure appear more fully from the following description.

### BRIEF DESCRIPTION OF THE DRAWINGS

The accompanying drawings are included to provide an understanding of the disclosure and are incorporated in and constitute a part of this specification. The drawings illustrate example embodiments and, together with the specification, serve to explain the principles of the technology.

FIG. 1 is a perspective view showing a magnetoresistive element according to an example embodiment of the disclosure.

FIG. 2 is a cross-sectional view showing a structure including an antiferromagnetic layer and a first magnetic layer according to a first example embodiment of the disclosure.

FIG. 3 is magnetization curves of a structure including the first magnetic layer and the antiferromagnetic layer of the magnetoresistive element according to the first example embodiment of the disclosure.

FIG. 4 is a partially enlarged view of the magnetization curves shown by enlarging a part of the magnetization curves shown in FIG. 3.

FIG. 5 is magnetization curves of a structure including a first magnetic layer and an antiferromagnetic layer of a magnetoresistive element according to an aspect of a comparative example.

FIG. 6 is a partially enlarged view of the magnetization curves shown by enlarging a part of the magnetization curves shown in FIG. 5.

FIG. 7 is a cross-sectional view showing a structure including an antiferromagnetic layer and a first magnetic layer according to a second example embodiment of the disclosure.

FIG. 8 is a plan view showing a magnetic sensor according to an example embodiment of the disclosure.

FIG. 9 is a circuit diagram showing a circuit configuration of the magnetic sensor according to the example embodiment of the disclosure.

FIG. 10 is a plan view showing a part of the magnetic sensor according to the example embodiment of the disclosure.

FIG. 11 is an output diagram of a half-bridge circuit of the magnetic sensor according to the example embodiment of the disclosure.

### DETAILED DESCRIPTION

An object of the disclosure is to provide a magnetoresistive element including a first magnetic layer as a perpendicular magnetization film with improved magnetization stability of the first magnetic layer, and a magnetic sensor including the magnetoresistive element.

In the following, some example embodiments and modification examples of the disclosure are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions. The description will be made in the following order.

### Description of Magnetoresistive Element According to Example Embodiment

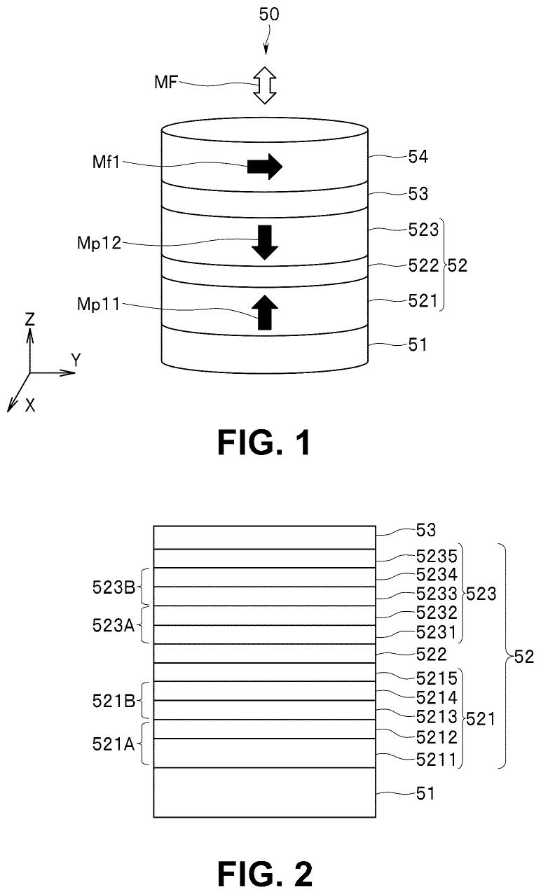

First, with reference to FIG. 1, a schematic configuration of a magnetoresistive element according to an example embodiment of the disclosure will be described.

The X direction, the Y direction, and the Z direction shown in FIG. 1 are orthogonal to one another. The opposite directions to the X, Y, and Z directions are defined as −X, −Y, and −Z directions, respectively. In the example embodiment, one direction perpendicular to the in-plane direction of each layer constituting the magnetoresistive element, particularly, the stacking direction from an antiferromagnetic layer 51 to a second magnetic layer 54 shown in FIG. 1, is defined as the Z direction.

As used herein, the term “above” refers to a position located ahead a given reference position in the Z direction, and “below” refers to a position opposite from the “above” position, i.e., a position ahead in the −Z direction, with respect to the given reference position. For each component of the magnetic sensor 1, a surface located at an end in the Z direction is referred to as an “upper surface”, and a surface located at an end in the −Z direction is referred to as a “lower surface”.

A magnetoresistive element 50 according to the example embodiment is a magnetoresistive element (hereinafter, referred to as an “MR element 50”) configured to have a resistance changing according to an external magnetic field.

The MR element 50 includes a first magnetic layer 52, a second magnetic layer 54 whose magnetization direction Mf1 changes according to an external magnetic field MF, a spacer layer 53 arranged between the first magnetic layer 52 and the second magnetic layer 54, and an antiferromagnetic layer 51 arranged on a side of the first magnetic layer 52 opposite to the spacer layer 53.

The MR element 50 has a structure in which the antiferromagnetic layer 51, the first magnetic layer 52, the spacer layer 53, and the second magnetic layer 54 are stacked in this order from the bottom of FIG. 1. Note that the order of stacking may be reversed. Specifically, the structure may be a structure in which the second magnetic layer 54, the spacer layer 53, the first magnetic layer 52, and the antiferromagnetic layer 51 are stacked in this order from the bottom of FIG. 1.

The first magnetic layer 52 includes an outer magnetic layer 521, an inner magnetic layer 523, and a nonmagnetic layer 522 arranged between the outer magnetic layer 521 and the inner magnetic layer 523. The inner magnetic layer 523 is arranged on a side farther from the antiferromagnetic layer 51 than the outer magnetic layer 521 is. In other words, the outer magnetic layer 521 is arranged on a side closer to the antiferromagnetic layer 51 than the inner magnetic layer 523 is. In FIG. 1, the inner magnetic layer 523 is arranged above the outer magnetic layer 521. As shown in FIG. 1, the outer magnetic layer 521 is in contact with the antiferromagnetic layer 51.

As shown in FIG. 1, a magnetization direction Mp11 of the outer magnetic layer 521 and a magnetization direction Mp12 of the inner magnetic layer 523 are defined to be perpendicular to the in-plane direction and opposite to each other. As shown in FIG. 1, the magnetization direction Mp11 of the outer magnetic layers 521 is the Z direction, and the magnetization direction Mp12 of the inner magnetic layer 523 is the −Z direction.

In the example embodiment, the magnetization direction Mp11 of the outer magnetic layer 521 includes a component in the Z direction, and the magnetization direction Mp12 of the inner magnetic layer 523 includes a component in the −Z direction. The magnetization direction of the outer magnetic layer 521 may include a component in a direction other than the Z direction, but mainly includes a component in the Z direction. Hence, the outer magnetic layer 521 is regarded as being magnetized in the Z direction, and the magnetization direction Mp12 is indicated as the Z direction. The magnetization direction of the inner magnetic layer 523 may include a component in a direction other than the −Z direction, but mainly includes a component in the −Z direction. Hence, the inner magnetic layer 523 is regarded as being magnetized in the −Z direction, and the magnetization direction Mp12 is indicated as the −Z direction. In the specification of the present application, the expression “including a component” means that the direction including the component is dominant, and the direction of the component is indicated in the drawings.

The nonmagnetic layer 522 located between the outer magnetic layer 521 and the inner magnetic layer 523 is in contact with each of the outer magnetic layer 521 and the inner magnetic layer 523.

The nonmagnetic layer 522 is a nonmagnetic thin metal spacer and is formed of, for example, Ru, Ir, or Cu, but Ru may be used in a given aspect.

The stack structure of the outer magnetic layer 521, the nonmagnetic layer 522, and the inner magnetic layer 523 is called an SAF (Synthetic AntiFerromagnetic) structure. Specifically, antiferromagnetic exchange coupling occurs between the outer magnetic layer 521 and the inner magnetic layer 523, and thus the magnetization direction Mp11 of the outer magnetic layer 521 and the magnetization direction Mp12 of the inner magnetic layer 523 are antiparallel to each other.

As shown in FIG. 1, the antiferromagnetic layer 51 is in contact with the outer magnetic layer 521, and an exchange bias magnetic field is generated between the antiferromagnetic layer 51 and the outer magnetic layer 521. The exchange bias magnetic field is generated at a contact surface (interface) between the antiferromagnetic layer 51 and the outer magnetic layer 521, and acts to fix the magnetization direction Mp11 of the outer magnetic layer 521 in the Z direction. The antiferromagnetic layer 51 may be formed of, for example, IrMn or PtMn.

By the antiferromagnetic exchange coupling occurring between the outer magnetic layer 521 and the inner magnetic layer 523, the magnetization direction Mp12 of the inner magnetic layer 523 is fixed in the −Z direction opposite to the magnetization direction Mp11 of the outer magnetic layer 521.

Thus, the first magnetic layer 52 has a fixed magnetization direction and is also referred to as a “magnetization pinned layer”. When the external magnetic field MF having magnitude exceeding the reverse magnetic field of the outer magnetic layer 521 or the inner magnetic layer 523 acts on the MR element 50, the SAF structure of the first magnetic layer 52 is collapsed once, but when the external magnetic field MF is weakened, the external magnetic field MF acts so that the SAF structure returns to an original magnetization state again.

The magnetization direction Mf1 of the second magnetic layer 54 is oriented, for example, in the Y direction of the in-plane direction shown in FIG. 1, and the magnetization direction Mf1 changes according to the external magnetic field MF. Note that the magnetization direction Mf1 of the second magnetic layer 54 shown in FIG. 1 is in a magnetization state where the external magnetic field MF does not act on the second magnetic layer 54, i.e., a magnetization state of a zero magnetic field. The magnetization direction Mf1 of the second magnetic layer 54 may be the X direction of the in-plane direction, or may be an in-plane direction between the X direction and the Y direction. The magnetization direction Mf1 may be oriented in a direction other than the in-plane direction depending on the application of the MR element 50. The magnetization direction Mf1 of the second magnetic layer 54 may be oriented in a given specific direction by the magnetic shape anisotropy, or may be acted to be oriented in a given specific direction by receiving a bias magnetic field from a bias layer (not shown). The planar shape of the second magnetic layer 54 can be a perfect circle, an ellipse, a square, a rectangle, or any other regular polygon, and is not limited to a specific shape. The layers arranged above the second magnetic layer 54 can also be formed in a similar planar shape to that of the second magnetic layer 54. The layers from the antiferromagnetic layer 51 to the spacer layer 53 other than the second magnetic layer 54 and the layers (not shown) arranged below the antiferromagnetic layer 51 may be formed in a similar planar shape as that of the second magnetic layer 54 or may each be formed in a planar shape different in shape from the second magnetic layer 54 or in a planar shape different in size from the second magnetic layer 54.

The second magnetic layer 54 is formed of a ferromagnetic material, for example, NiFe, CoFe, or CoFeB. Alternatively, the second magnetic layer 54 may have a structure in which a plurality of magnetic layers having different compositions are stacked.

The second magnetic layer 54 is also referred to as a “free layer” because the magnetization direction Mf1 varies depending on the external magnetic field MF.

The spacer layer 53 is formed of an electrically insulating layer or a nonmagnetic metal layer. When the spacer layer 53 is formed of an electrically insulating layer, the spacer layer 53 is also referred to as a tunnel barrier layer and is formed of, for example, MgO. The MR element 50 in which the spacer layer 53 is a tunnel barrier layer is referred to as a TMR (Tunneling Magneto Resistance) element. In contrast, when the spacer layer 53 is formed of a nonmagnetic metal layer, the spacer layer 53 is formed of, for example, Cu. The MR element 50 in which the spacer layer 53 is a nonmagnetic metal layer is referred to as a GMR (Giant Magneto Resistance) element. Although not shown, in each of a TMR element and a CPP (Current Perpendicular-to-Plane) type GMR element, an electrode layer is arranged below the antiferromagnetic layer 51 and above the second magnetic layer 54, and a current flows in a perpendicular direction with respect to the in-plane direction of the MR element 50. Although not shown, in a CIP (Current In-Plane) type GMR element, electrode layers are arranged on both sides of the MR element 50, and a current flows in the in-plane direction of the MR element 50.

The MR element 50 may include, for example, a cap layer (not shown) arranged on the second magnetic layer 54 and the like.

### First Example Embodiment

FIG. 2 is a cross-sectional view showing a structure including the antiferromagnetic layer 51 and the first magnetic layer 52 according to a first example embodiment of the disclosure. FIG. 2 is a cross-sectional view showing only a part corresponding to the antiferromagnetic layer 51, the first magnetic layer 52, and the spacer layer 53 shown in FIG. 1, in an enlarged manner.

As shown in FIG. 2, the outer magnetic layer 521 and the inner magnetic layer 523 constituting the first magnetic layer 52 are formed in a stack structure of a plurality of metal layers.

The outer magnetic layer 521 has a structure in which a metal layer 5211, a metal layer 5212, a metal layer 5213, a metal layer 5214, and a metal layer 5215 are stacked between the antiferromagnetic layer 51 and the nonmagnetic layer 522 in this order from the bottom, which is the antiferromagnetic layer 51 side. The inner magnetic layer 523 has a structure in which a metal layer 5231, a metal layer 5232, a metal layer 5233, a metal layer 5234, and a metal layer 5235 are stacked between the nonmagnetic layer 522 and the spacer layer 53 in this order from the bottom, which is the nonmagnetic layer 522 side.

The outer magnetic layer 521 includes a stack 521A in which the metal layer 5211 and the metal layer 5212 are stacked together and a stack 521B in which the metal layer 5213 and the metal layer 5214 are stacked together. The inner magnetic layer 523 includes a stack 523A in which the metal layer 5231 and the metal layer 5232 are stacked together and a stack 523B in which the metal layer 5233 and the metal layer 5234 are stacked together. In each of the stacks 521A, 521B, 523A, and 523B, the metal layer 5211, 5213, 5231, or 5233 located on the side closer to the antiferromagnetic layer 51, i.e., bottom in the corresponding one of the stacks 521A, 521B, 523A, and 523B, is defined as a “first metal layer”, and the metal layer 5212, 5214, 5232, or 5234 located on the side farther from the antiferromagnetic layer 51, i.e., above in the corresponding one of the stacks 521A, 521B, 523A, and 523B, is defined as a “second metal layer”.

As shown in FIG. 2, the first magnetic layer 52 includes a stack structure in which the stacks 521A, 521B, 523A, and 523B in each of which a corresponding one of the first metal layers 5211, 5213, 5231, and 5233 and a corresponding one of the second metal layers 5212, 5214, 5232, and 5234 are repeatedly stacked. These stacks are repeatedly stacked in both the outer magnetic layer 521 and the inner magnetic layer 523. However, the stack in which the first metal layer and the second metal layer are stacked together may have a structure in which the first metal layer and the second metal layer are repeatedly stacked only in the outer magnetic layer 521. In other words, the inner magnetic layer 523 may have a single-layer structure of a metal layer or may have a stack structure of metal layers different from the first metal layer and the second metal layer. Alternatively, the first magnetic layer 52 may be constituted only of the outer magnetic layer 521 without providing the inner magnetic layer 523.

An exchange bias magnetic field generated between a magnetization pinned layer as a perpendicular magnetization film and an antiferromagnetic layer is small in some cases. Hence, when an external magnetic field large enough to reverse the magnetization direction of the magnetization pinned layer is applied and then the external magnetic field is returned to zero, the magnetization direction of the magnetization pinned layer does not return to the original perpendicular direction in some cases. This consequently lowers the output of a magnetic sensor or prevents the output from being obtained, which makes the output unstable in some cases.

In the MR element 50 of the disclosure, an exchange bias magnetic field of sufficient magnitude is generated between the first magnetic layer 52 and the antiferromagnetic layer 51, and hence the magnetization of the first magnetic layer 52 can be appropriately fixed.

The first metal layers 5211, 5213, 5231, and 5233 of the disclosure are divided into a specific metal layer 5211 in contact with the antiferromagnetic layer 51 and other metal layers 5213, 5231, and 5233 not in contact with the antiferromagnetic layer 51.

The specific metal layer 5211 is formed with a composition different from those of the other metal layers 5213, 5231, and 5233.

The specific metal layer 5211 is in contact with the antiferromagnetic layer 51, and an exchange bias magnetic field is generated between the specific metal layer 5211 and the antiferromagnetic layer 51. Hence, a composition that increases the magnitude of the exchange bias magnetic field generated between the antiferromagnetic layer 51 and the specific metal layer 5211 is selected for the specific metal layer 5211. In contrast, a composition that increases the perpendicular magnetic anisotropy energy is selected as a composition different from that of the specific metal layer 5211, for each of the other metal layers 5213, 5231, and 5233 other than the specific metal layer 5211 and not in contact with the antiferromagnetic layer 51 among the first metal layers 5211, 5213, 5231, and 5233.

For example, the specific metal layer 5211 may have a composition containing Co and Fe. This increases the magnitude of the exchange bias magnetic field generated between the specific metal layer 5211 and the antiferromagnetic layer 51. The composition of the specific metal layer 5211 is expressed as Co_{X}Fe_{100-X} (X is at %), and X can be set to 10 or more and 95 or less. By adjusting the composition ratio of Co and Fe as described above, the exchange bias magnetic field generated between the specific metal layer 5211 and the antiferromagnetic layer 51 can be effectively increased, which makes the action of fixing the magnetization of the first magnetic layer 52 stronger.

In a given aspect, X may be 30 or more and 80 or less, or may be 50 or more and 70 or less. With this, the exchange bias magnetic field can be increased more effectively.

The film thickness of the specific metal layer 5211 is not limited, but may be larger than the film thickness of each of the other metal layers 5213, 5231, and 5233 or may be substantially the same as the film thickness of each of the other metal layers 5213, 5231, and 5233. The film thickness of the specific metal layer 5211 is not limited, but may be 6 Å or more and 20 Å or less or may be 7 Å or more and 15 Å or less. The film thickness of each of the other metal layers 5213, 5231, and 5233 is not limited, but may be 3 Å or more and 8 Å or less.

For the specific metal layer 5211 in contact with the antiferromagnetic layer 51, a composition having a crystal structure that increases the exchange bias magnetic field generated between the specific metal layer 5211 and the antiferromagnetic layer 51 can be selected.

The exchange bias magnetic field is generated at a contact surface between the antiferromagnetic layer 51 and the specific metal layer 5211. The compositions of the antiferromagnetic layer 51 and the specific metal layer 5211 are selected so that the crystal structure of the specific metal layer 5211 at the contact surface is different from the crystal structure of the antiferromagnetic layer 51 at the contact surface. For example, the crystal structure of the antiferromagnetic layer 51 at the contact surface may be a face-centered cubic structure. The crystal structure of the specific metal layer 5211 at the contact surface may be a body-centered cubic structure. For example, when the antiferromagnetic layer 51 is formed of IrMn, the crystal structure of the antiferromagnetic layer 51 at the crystal plane is a face-centered cubic structure. When the specific metal layer 5211 is formed of CoFe, the crystal structure of the specific metal layer 5211 at the contact surface is a body-centered cubic structure. As described above, the crystal structures at the contact surface between the specific metal layer 5211 and the antiferromagnetic layer 51 are made different from each other, and as an example, compositions are appropriately selected so that the crystal structure of the specific metal layer 5211 at the contact surface is a body-centered cubic structure and the crystal structure of the antiferromagnetic layer 51 at the contact surface is a face-centered cubic structure, which can increase the magnitude of the exchange bias magnetic field generated between the antiferromagnetic layer 51 and the specific metal layer 5211.

Note that the crystal structures of the antiferromagnetic layer 51 and the specific metal layer 5211 described above are sufficient as long as the crystal structures are satisfied at the contact surface. Hence, the entire antiferromagnetic layer 51 and the entire specific metal layer 5211 may have the above-described crystal structures, but this is not restrictive.

The other metal layers 5213, 5231, and 5233 may be of Co, for example. The second metal layers 5212, 5214, 5232, and 5234 may be of Pt or Pd, for example. As described above, the first metal layers 5211, 5213, 5231, and 5233 are each formed of or each include a ferromagnetic material, and the second metal layers 5212, 5214, 5232, and 5234 are each formed of or each include a paramagnetic platinum group element.

The second metal layers 5212, 5214, 5232, and 5234 have action of increasing the spin polarization in a perpendicular direction of the first metal layers 5211, 5213, 5231, and 5233. Accordingly, the second metal layers 5212, 5214, 5232, and 5234 can be interpreted as “polarization layers”.

For example, the stack 521A in contact with the antiferromagnetic layer 51 has a stack structure of CoFe and Pt, and the other stacks 521B, 523A, and 523B each have a stack structure of Co and Pt. In the example of FIG. 2, the outer magnetic layer 521 and the inner magnetic layer 523 each have odd-numbered layers and the same number of layers, and the third metal layers 5215 and 5235 not included in the stacks 521A, 521B, 523A, and 523B are present in the outer magnetic layer 521 and the inner magnetic layer 523, respectively. The third metal layer 5215 arranged in the outer magnetic layer 521 is in contact with the nonmagnetic layer 522, and the third metal layer 5235 arranged on the inner magnetic layer 523 is in contact with the spacer layer 53. Each of the third metal layers 5215 and 5235 is located at the uppermost layer of the corresponding one of the outer magnetic layer 521 and the inner magnetic layer 523. In the first example embodiment shown in FIG. 2, the third metal layers 5215 and 5235 can be formed with the same composition as those of the other metal layers 5213, 5231, and 5233 of the first metal layers 5211, 5213, 5231, and 5233. The third metal layers 5215 and 5235 can be formed of Co, for example, as the other metal layers 5213, 5231, and 5233.

In the compositions described above, as an example of the composition of each metal layer of the outer magnetic layer 521 and the inner magnetic layer 523, the first magnetic layer 52 can be stacked with the specific metal layer (first metal layer) 5211: CoFe/second metal layer 5212: Pt/other metal layer (first metal layer) 5213: Co/second metal layer 5214: Pt/third metal layer 5215: Co/nonmagnetic layer 522: Ru/other metal layer (first metal layer) 5231: Co/second metal layer 5232: Pt/other metal layer (first metal layer) 5233: Co/second metal layer 5234: Pt/third metal layer 5235: Co in order from the antiferromagnetic layer 51 side. Note that the third metal layer 5215 may have a stack structure of a ferromagnetic layer constituting the third metal layer 5215 and a thin nonmagnetic layer of Ta, W, Mo, or the like. The nonmagnetic layer may be arranged on the second metal layer 5214 side of the ferromagnetic layer or may be inserted between ferromagnetic layers. For example, it may be configured with the third metal layer 5215: W/Co. The number of repetitions of the second metal layer and the other metal layers is not limited. In FIG. 2, the number of repetitions of Pt/Co in the outer magnetic layer 521 is two but may be three or more. This similarly applies to the inner magnetic layer 523. This also similarly applies to a second example embodiment and other example embodiments to be described later.

Next, the operation and effects of the MR element 50 including the stack of the antiferromagnetic layer 51 and the first magnetic layer 52 of the first example embodiment will be described. As already described, the first magnetic layer 52 includes the stacks 521A, 521B, 523A, and 523B in which the first metal layers 5211, 5213, 5231, and 5233 and the second metal layers 5212, 5214, 5232, and 5234 are stacked together. Among the first metal layers 5211, 5213, 5231, and 5233, the specific metal layer 5211 in contact with the antiferromagnetic layer 51 is formed with a composition different from those of the other metal layers 5213, 5231, and 5233 not in contact with the antiferromagnetic layer 51. With this, a composition that increases the magnitude of the exchange bias magnetic field generated between the antiferromagnetic layer 51 and the specific metal layer 5211 can be selected for the specific magnetic layer 5211, and a composition that increases the perpendicular magnetic anisotropy energy can be selected for each of the other metal layers 5213, 5231, and 5233. With the above, in the zero magnetic field state, the first magnetic layer 52 can be formed as a perpendicular magnetization film in which the magnetization is stably fixed in the perpendicular direction, to thereby be able to improve the magnetization stability of the first magnetic layer 52.

The MR element 50 according to the example embodiment can be applied to, for example, a magnetic sensor. In the magnetic sensor, an external magnetic field MF in a range (sensing range) of a perpendicular magnetic field in the Z direction and a perpendicular magnetic field in the −Z direction shown in FIG. 1 acts on the MR element 50. By forming the first magnetic layer 52 to have the SAF structure, the sensing range for the external magnetic field in the perpendicular direction can be increased, and the leakage magnetic field can be reduced. In this case, even if the magnetization directions Mp11 and Mp12 of the first magnetic layer 52 are reversed by the action of the external magnetic field MF exceeding the sensing range, the magnetization directions Mp11 and Mp12 can be quickly returned to the original magnetization directions Mp11 and Mp12 when the external magnetic field MF is set to certain magnitude or less. The operation of the magnetizing directions Mp11 and Mp12 will be described in more detail by using magnetization curves.

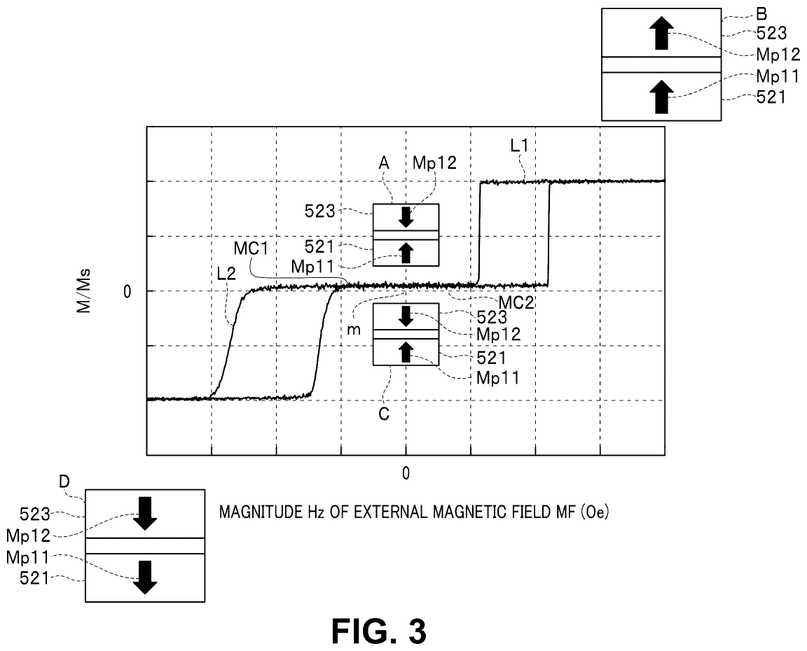

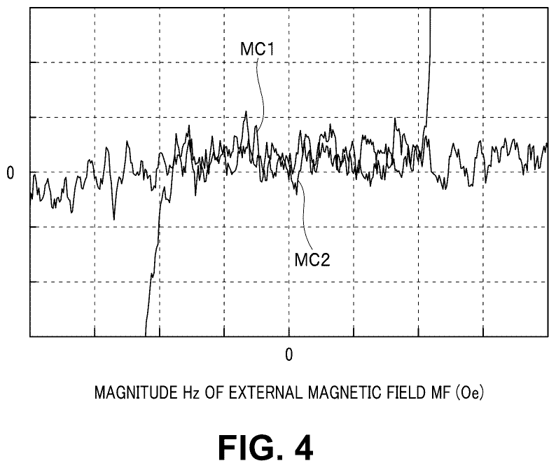

FIG. 3 shows magnetization curves of a structure including the antiferromagnetic layer 51 and the first magnetic layer 52 of the first example embodiment. The composition of the structure of the magnetization curves shown in FIG. 3 is formed with IrMn/CoFe/Pt/Co/Pt/Co/Ru/Co/Pt/Co/Pt/Co stacked in this order from the bottom. The horizontal axis in FIG. 3 represents the magnitude Hz of the external magnetic field MF. The vertical axis in FIG. 3 represents normalized magnetization M/Ms. The normalized magnetization M/Ms can be obtained by dividing a magnetic moment M of the first magnetic layer 52 by saturation magnetization Ms. Note that the scales of the horizontal axis and the vertical axis can be freely defined. This similarly applies to FIG. 4 to FIG. 6 and FIG. 11 to be described later. Application of the external magnetic field MF from the zero magnetic field in the Z direction shown in FIG. 1 is described as a positive external magnetic field in FIG. 3 (external magnetic field MF on the right side of the zero magnetic field in the drawing), and application of the external magnetic field MF from the zero magnetic field in the −Z direction is described as a negative external magnetic field in FIG. 3 (external magnetic field MF on the left side of the zero magnetic field in the drawing).

In FIG. 3, magnetization states A to D for magnitudes Hz of the respective external magnetic fields, which schematically illustrate the magnetization directions of the inner magnetic layer 523 and the outer magnetic layer 521 with respect to the magnitude Hz of the external magnetic field MF, are also shown on the graph of the magnetization curves.

At the zero magnetic field, which is the starting point of the magnetization curves, the magnetization state is the magnetization state A. Specifically, the magnetization directions Mp11 and Mp12 of the outer magnetic layer 521 and the inner magnetic layer 523 are antiparallel to each other and fixed in the perpendicular directions. In the magnetization state A, the magnetization direction Mp12 of the inner magnetic layer 523 is downward, and the magnetization direction Mp11 of the outer magnetic layer 521 is upward. Note that, in the following, the expressions “original perpendicular direction” and “original perpendicular magnetization film” may be used, and these refer to the magnetization state A.

When the positive external magnetic field MF is increased from the zero magnetic field, the magnetizing direction Mp12 of the inner magnetic layer 523 is reversed to enter the magnetization state B. In the magnetization state B, the magnetization directions Mp11 and Mp12 of the outer magnetic layer 521 and the inner magnetic layer 523 are both upward. In the course of gradually weakening the external magnetic field MF from the magnetization state B to approach the zero magnetic field, the magnetization direction Mp12 of the inner magnetic layer 523 is reversed again to return to the original and enter the magnetization state C. In the magnetization state C, the magnetization direction Mp12 of the inner magnetic layer 523 is downward, and the magnetization direction Mp11 of the outer magnetic layer 521 is upward, as in the magnetization state A at the time of the initial zero magnetic field. Thus, on the side where the magnitude Hz of the external magnetic field shown in FIG. 3 is positive, a first hysteresis loop L1 is formed. When the external magnetic field MF is increased to such an extent that the magnetization direction Mp12 the inner magnetic layers 523 is reversed and is thereafter gradually decreased, the first hysteresis loop L1 is formed with a given specific hysteresis width by the coercive force of the magnetization of the inner magnetic layers 523.

In contrast, when the negative external magnetic field MF is increased from the zero magnetic field, the magnetization direction Mp11 of the outer magnetic layer 521 is then reversed to enter the magnetization state D. In the magnetization state D, the magnetization directions Mp11 and Mp12 of the inner magnetic layer 523 and the outer magnetic layer 521 are both downward. In the course of gradually weakening the external magnetic field MF from the magnetization state D to approach the zero magnetic field, the magnetization direction Mp11 of the outer magnetic layer 521 is reversed again to return to the original and enter the magnetization state C. In the magnetization state C, the magnetization direction Mp12 of the inner magnetic layer 523 is downward, and the magnetization direction Mp11 of the outer magnetic layer 521 is upward, as in the magnetization state A. Thus, on the side where the magnitude Hz of the external magnetic field MF shown in FIG. 3 is negative, a second hysteresis loop L2 is formed. The second hysteresis loop L2 is also formed to have a given specific hysteresis width, as the first hysteresis loop L1.

The first hysteresis loop L1 is formed based on the reversal of the magnetization direction Mp12 of the inner magnetic layer 523, and the second hysteresis loop L2 is formed based on the reversal of the magnetization direction Mp11 of the outer magnetic layer 521.

In the first example embodiment, the magnitude of the exchange bias magnetic field generated between the specific metal layer 5211 and the antiferromagnetic layer 51 is great. The perpendicular magnetic anisotropy energy of the outer magnetic layer 521 is smaller than the perpendicular magnetic anisotropy energy of the inner magnetic layer 523. In other words, the perpendicular magnetic anisotropy energy of the inner magnetic layer 523 is greater than the perpendicular magnetic anisotropy energy of the outer magnetic layer 521.

Based on these magnetic actions, when the external magnetic field MF in the positive direction is increased, the magnetization direction Mp12 of the inner magnetic layer 523 is quickly reversed from the downward direction to the upward direction while the magnetization direction Mp11 of the outer magnetic layer 521 is appropriately fixed in the upward direction, and when the external magnetic field MF is decreased from this state, the magnetization direction Mp12 of the inner magnetic layer 523 that has been reversed is quickly returned to the original downward direction, and the rising and falling of the magnetization curves of the first hysteresis loop L1 change steeply as in FIG. 3. In contrast, when the external magnetic field MF in the negative direction is increased, the magnetization direction Mp11 of the outer magnetic layer 521 is gently reversed from the upward direction to the downward direction while the magnetization direction Mp12 of the inner magnetic layer 523 is appropriately fixed in the downward direction, and when the external magnetic field MF is decreased from this state, the magnetization direction Mp12 of the outer magnetic layer 521 that has been reversed is quickly returned to the original upward direction, and the rising and falling of the magnetization curves of the second hysteresis loop L2 change gently. As a result, as shown in FIG. 3, the first hysteresis loop L1 and the second hysteresis loop L2 appear asymmetrically with respect to a magnetization point m of the zero magnetic field as a center of point symmetry.

In the first example embodiment, the magnetization direction Mp12 of the inner magnetic layer 523 that has been reversed is returned to the original perpendicular direction at the zero magnetic field at the time of transition from the first hysteresis loop L1 to the second hysteresis loop L2, and the magnetization direction Mp11 of the outer magnetic layer 521 that has been reversed is returned to the original perpendicular direction at the zero magnetic field at the time of transition from the second hysteresis loop L2 to the first hysteresis loop L1. In this way, in the course of bringing the external magnetic field MF close to the zero magnetic field, the magnetization directions Mp11 and Mp12 of the inner magnetic layer 523 and the outer magnetic layer 521 can be returned to the original perpendicular directions. In the magnetization curves in FIG. 3, it is understood that magnetization curves MC1 and MC2 during the transition from the first hysteresis loop L1 to the second hysteresis loop L2 and during the transition from the second hysteresis loop L2 to the first hysteresis loop L1 overlap each other, and thus the inner magnetic layer 523 and the outer magnetic layer 521 appropriately hold the original perpendicular magnetic films in the state of the zero magnetic field.

The expression “magnetization curves MC1 and MC2 overlap each other” does not mean matching in a strict sense. In other words, there may be portions that theoretically match but do not appear to match due to the presence of noise or drift in measurement. Hence, as long as the conditions defined below are satisfied, it can be regarded that the magnetization curves MC1 and MC2 match.

FIG. 4 is a partially enlarged view of the magnetization curves shown by enlarging a part of the magnetization curves shown in FIG. 3. As shown in FIG. 4, the normalized magnetization M/Ms of the magnetization curve MC1 during the transition from the first hysteresis loop L1 to the second hysteresis loop L2 and the normalized magnetization M/Ms of the magnetization curve MC2 during the transition from the second hysteresis loop L2 to the first hysteresis loop L1 have very close values. When the difference in average value between the normalized magnetizations M/Ms is 0.02 or less, the normalized magnetizations M/Ms can be regarded as matching, although this is not restrictive. The average values of the normalized magnetizations M/Ms of the magnetization curves MC1 and MC2 are each, for example, a value obtained by averaging the normalized magnetizations M/Ms in a range of 50% of the width of the external magnetic field MF between the hysteresis loops L1 and L2 with Hz=0 as the center. The difference in average value between the normalized magnetizations M/Ms being 0.02 or less is the basis for regarding the magnetization curves MC1 and MC2 as matching, but the matching may be defined as follows according to the measurement situation and the like. For example, when the difference in average value between the normalized magnetizations M/Ms of the magnetization curve MC1 and the normalized magnetizations M/Ms of the magnetization curve MC2 is 1/50 or less of the difference between the maximum value and the minimum value of the normalized magnetizations M/Ms of the hysteresis loops L1 and L2 shown in FIG. 3, the normalized magnetizations M/Ms can be regarded as matching. When the region where the difference in average value between the normalized magnetizations M/Ms of the MC1 and the normalized magnetizations M/Ms of the magnetization curve MC2 falls within the above range is 50% or more, 60% or more, 70% or more, 80% or more, 90% or more, or 95% or more of the width of the external magnetic field MF between the hysteresis loops L1 and L2, the magnetization curves MC1 and MC2 can be regarded as overlapping each other during the transition from the first hysteresis loop L1 to the second hysteresis loop L2.

As described above, in the first example embodiment, even when the external magnetic field MF reverses either of the magnetization directions Mp11 and Mp12 of the outer magnetic layer 521 and the inner magnetic layer 523, the magnetization direction Mp11 or Mp12 that has been reversed can be reversed again and easily returned to the original perpendicular direction in the course of bringing the external magnetic field MF close to the zero magnetic field. This can improve the magnetization stability of the first magnetic layer 52 in the zero magnetic field.

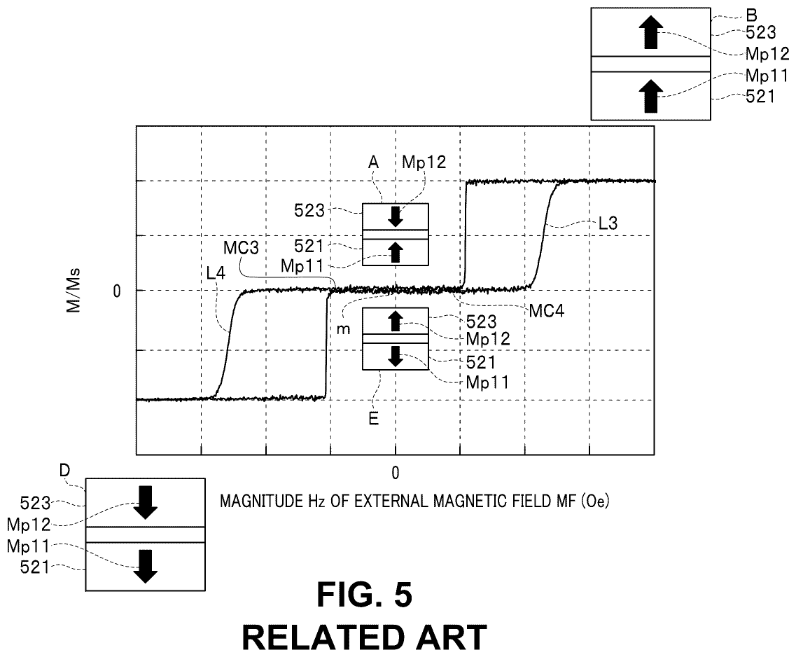

Meanwhile, FIG. 5 is magnetization curves of a structure including a first magnetic layer and an antiferromagnetic layer of a magnetoresistive element according to an aspect of a comparative example.

In the comparative example, the specific metal layer 5211 is made of Co as the other metal layers 5213, 5231, and 5233. The compositions of the other layers are the same as those in FIG. 3. Specifically, the composition of the structure of the magnetization curves shown in FIG. 5 is formed with IrMn/Co/Pt/Co/Pt/Co/Ru/Co/Pt/Co/Pt/Co stacked in this order from the bottom. In the comparative example, the crystal structures at the contact surface between the specific metal layer 5211 and the antiferromagnetic layer 51 are both a face-centered cubic structure.

In a first hysteresis loop L3 and a second hysteresis loop L4 appearing in the magnetization curves in FIG. 5, one of the rising and falling of the magnetization curves changes steeply, and the other changes gently. The first hysteresis loop L3 and the second hysteresis loop L4 appear substantially symmetrically with respect to the magnetization point m of the zero magnetic field as a center of point symmetry. The first hysteresis loop L3 and the second hysteresis loop L4 shown in FIG. 5 have slightly different hysteresis widths because of the presence of a minute exchange bias magnetic field, but have substantially point-symmetrical shapes except for this point. As described above, in the magnetization curves of the first example embodiment shown in FIG. 3, the first hysteresis loop L1 and the second hysteresis loop L2 do not appear point-symmetrically with respect to the magnetizing point m of the zero magnetic field, whereas in the magnetization curves of the comparative example shown in FIG. 5, the first hysteresis loop L3 and the second hysteresis loop L4 appear substantially point-symmetrically.

In the comparative example of FIG. 5, the specific metal layer 5211 is formed of Co, and thus the magnitude of the exchange bias magnetic field generated between the specific metal layer 5211 and the antiferromagnetic layer 51 is smaller than that of the case where the specific metal layer 5211 is formed of CoFe as in the first example embodiment of FIG. 3. In the comparative example, the outer magnetic layer 521 and the inner magnetic layer 523 have the same stack structure, and the perpendicular magnetic anisotropy energy of the outer magnetic layer 521 and the perpendicular magnetic anisotropy energy of the inner magnetic layer 523 are about the same.

The exchange bias magnetic field Hex and the exchange coupling energy Jk shown in Table 1 below show the results of computations by an experiment with the respective stacks below each formed with the specific metal layer 5211 of Co, Co₉₀Fe₁₀, or Co₇₀Fe₃₀. The subscript attached to CoFe indicates the composition ratio in units of at %.

The stacks used in the experiment was Ta (20)/Ru (20)/Ta (20)/Ru (20)/IrMn (50)/specific metal layer (10)/[Pt (4)/Co (6)] stacked four times/Ru (10)/Ta (20). Each value in parentheses represents the film thickness, and the unit is Å.

TABLE 1

| Specific metal | Hex [Oe] | |
|---|---|---|
| layer 5211 | (1 Oe = 79.6 A/m) | Jk [erg/cm²] |
| Co | 300.2 | 0.151 |
| Co₉₀Fe₁₀ | 523.2 | 0.261 |
| Co₇₀Fe₃₀ | 848.2 | 0.440 |

As shown in Table 1, it was found that both the exchange bias magnetic field Hex and the exchange coupling energy Jk were larger by selecting Co₉₀Fe₁₀ and Co₇₀Fe₃₀ than by selecting Co for the specific metal layer 5211. It was also found that, by selecting Co₇₀Fe₃₀ for the specific metal layer 5211, the exchange coupling energy Jk could be increased to nearly three times as high as that of the case of selecting Co.

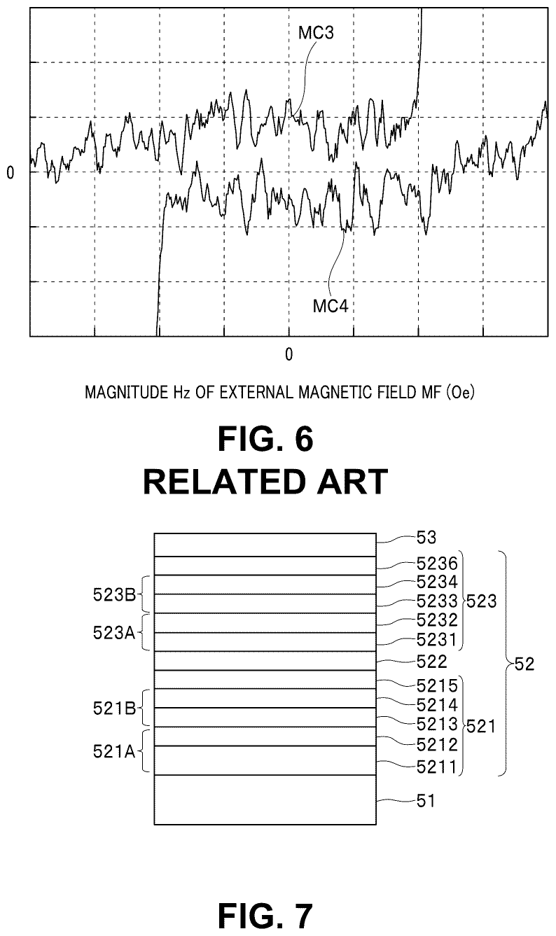

Thus, in the comparative example, the exchange bias magnetic field Hex and the exchange coupling energy Jk are smaller than those in the first example embodiment. Hence, as shown in FIG. 5, in the course of decreasing the positive external magnetic field MF to approach the zero magnetic field from the magnetization state B in which the positive external magnetic field MF is increased to reverse the magnetization direction Mp12 of the inner magnetic layer 523, or in the course of decreasing the negative external magnetic field MF to approach the zero magnetic field from the magnetization state D in which the negative external magnetic field MF is increased to reverse the magnetization direction Mp11 of the outer magnetic layer 521, the reversed magnetization directions Mp11 and Mp12 do not return to the original perpendicular directions. For example, in the course of decreasing the negative external magnetic field MF to approach the zero magnetic field from the magnetization state D in which the magnetization direction Mp11 of the outer magnetic layer 521 is reversed and the magnetization directions Mp11 and Mp12 of the outer magnetic layer 521 and the inner magnetic layer 523 are both downward, the magnetization direction Mp11 of the outer magnetic layer 521 is less likely to be returned to the original upward magnetization direction Mp11 due to the small magnitude of the exchange bias magnetic field generated between the antiferromagnetic layer 51 and the outer magnetic layer 521, and, for example, the magnetization direction Mp12 of the inner magnetic layer 523 having substantially the same perpendicular magnetic anisotropy energy as that of the outer magnetic layer 521 is not returned to the original magnetization state A in the zero magnetic field, for example, the magnetization direction Mp12 enters the magnetization state E in which the magnetization direction Mp12 is changed to be reversed by antiferromagnetic exchange coupling occurring between the outer magnetic layer 521 and the inner magnetic layer 523. This can be determined from the fact that magnetization curves MC3 and MC4 during the transition from the first hysteresis loop L3 to the second hysteresis loop L4 and during the transition from the second hysteresis loop L4 to the first hysteresis loop L3 do not completely overlap each other, as shown in FIG. 5 and FIG. 6. As described above, in the comparative example, the magnetization state of the first magnetic layer 52 is not fixed in the original perpendicular direction and becomes unstable in the zero magnetic field.

FIG. 6 is a partially enlarged view of the magnetization curves shown by enlarging a part of the magnetization curves shown in FIG. 5. As shown in FIG. 6, the magnetization curve MC3 during the transition from the first hysteresis loop L3 to the second hysteresis loop L4 and the magnetization curve MC4 during the transition from the second hysteresis loop L4 to the first hysteresis loop L3 do not overlap each other. In the comparative example, the difference in average value between the normalized magnetizations M/Ms of the magnetization curve MC1 and the normalized magnetizations M/Ms of the magnetization curve MC2 is larger than that in the case of FIG. 4. For example, in the comparative example, the difference in average value between the normalized magnetizations M/Ms of the magnetization curve MC1 and the normalized magnetizations M/Ms of the magnetization curve MC2 is larger than 0.02, or the difference in average value between the normalized magnetizations M/Ms of the magnetization curve MC3 and the normalized magnetizations M/Ms of the magnetization curve MC4 is larger than 1/50 of the difference between the maximum value and the minimum value of the normalized magnetizations M/Ms of the hysteresis loops L3 and L4 shown in FIG. 5. A method of obtaining the “average value” is the same as that described above with reference to FIG. 4, and thus reference should be made to the description.

In the first example embodiment, the magnitude of the exchange bias magnetic field generated between the antiferromagnetic layer 51 and the specific metal layer 5211 can be increased compared to that of the comparative example in which the specific metal layer 5211 has the same composition as those of the other metal layers 5213, 5231, and 5233. In the first example embodiment, the specific metal layer 5211 can be formed of a ferromagnetic material including, for example, Co and Fe. This increases the magnitude of the exchange bias magnetic field generated between the antiferromagnetic layer 51 and the first specific metal layer 5211, and the magnetization direction of the first magnetic layer 52 can be kept in the original perpendicular direction in the zero magnetic field, thereby exerting effects of being able to improve magnetization stability. In contrast, although the perpendicular magnetic anisotropy energy of the outer magnetic layer 521 is smaller than the perpendicular magnetic anisotropy energy of the inner magnetic layer 523, the perpendicular magnetic anisotropy energy of the inner magnetic layer 523 with respect to the sensibility can be increased by forming the first magnetic layer 52 to have the SAF structure, and thus the magnetization direction Mp12 of the inner magnetic layer 523 is less likely to be inclined by a magnetic field including an in-plane component, which can suppress decrease in sensibility due to an in-plane magnetic field.

### Second Example Embodiment

Next, a second example embodiment of the disclosure will be described with reference to FIG. 7. FIG. 7 is a cross-sectional view showing a structure including an antiferromagnetic layer 51 and a first magnetic layer 52 according to the second example embodiment, of a magnetoresistive element according to the example embodiment of the disclosure.

In the second example embodiment, a third metal layer 5236 of the inner magnetic layer 523 is in contact with the spacer layer 53, and the third metal layer 5236 is formed with a different composition from those of the first metal layers 5211, 5213, 5231, and 5233 and the second metal layers 5212, 5214, 5232, and 5234. For example, for the third metal layer 5236 in contact with the spacer layer 53, a composition that can increase the sensitivity (MR ratio) compared to that of a case where the third metal layer is formed with the compositions of the first metal layers 5211, 5213, 5231, and 5233. For example, the third metal layer 5236 is formed of CoFeB. In particular, when the MR element 50 is a TMR element, the sensitivity (MR ratio) can be effectively improved by forming the third metal layer 5236 with CoFeB. In the second example embodiment, the structures and compositions are the same as those of the first example embodiment except for the third metal layer 5236 in contact with the spacer layer 53. As an example, the first magnetic layer 52 in the second example embodiment shown in FIG. 7 can be stacked with the specific metal layer (first metal layer) 5211: CoFe/second metal layer 5212: Pt/other metal layer (first metal layer) 5213: Co/second metal layer 5214: Pt/third metal layer 5215: Co/nonmagnetic layer 522: Ru/other metal layer (first metal layer) 5231: Co/second metal layer 5232: Pt/other metal layer (first metal layer) 5233: Co/second metal layer 5234: Pt/third metal layer 5236: CoFeB in this order from the antiferromagnetic layer 51 side, for example. The third metal layer 5236 may have a stack structure of a ferromagnetic layer constituting the third metal layer 5236 and a thin nonmagnetic layer of Ta, W, Mo, or the like. The nonmagnetic layer may be arranged on the second metal layer 5234 side of the ferromagnetic layer or may be inserted between ferromagnetic layers. For example, it may be configured with the third metal layer 5236: W/CoFeB.

The operation and effects of the MR element 50 of the second example embodiment are similar to those of the MR element 50 of the first example embodiment. In other words, in the second example embodiment, the magnitude of the exchange bias magnetic field generated between the antiferromagnetic layer 51 and the specific metal layer 5211 can be increased compared to that in the comparative example in which the specific metal layer 5211 has the same composition as those of the other metal layers 5213, 5231, and 5233. In the second example embodiment, the perpendicular magnetic anisotropy energy of the inner magnetic layer 523 is greater than the perpendicular magnetic anisotropy energy of the outer magnetic layer 521. These magnetic actions can appropriately fix the magnetization direction of the first magnetic layer 52 in the zero magnetic field in the perpendicular direction. This can improve the magnetization stability of the first magnetic layer 52.

### Description of Magnetic Sensor According to Example Embodiment

The MR element 50 of the first example embodiment shown in FIG. 1 can be applied to the magnetic sensor 1.

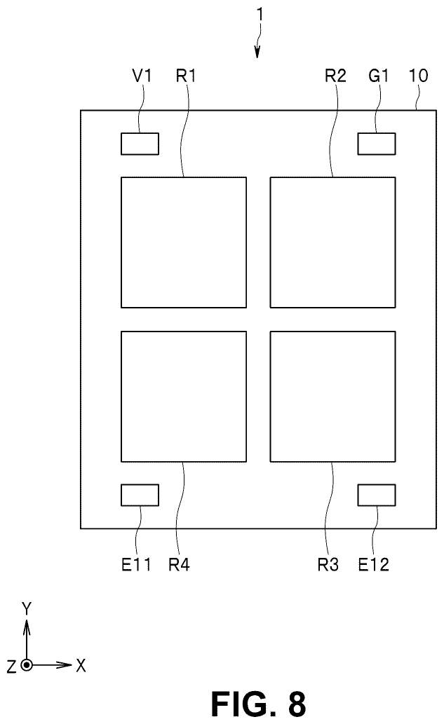

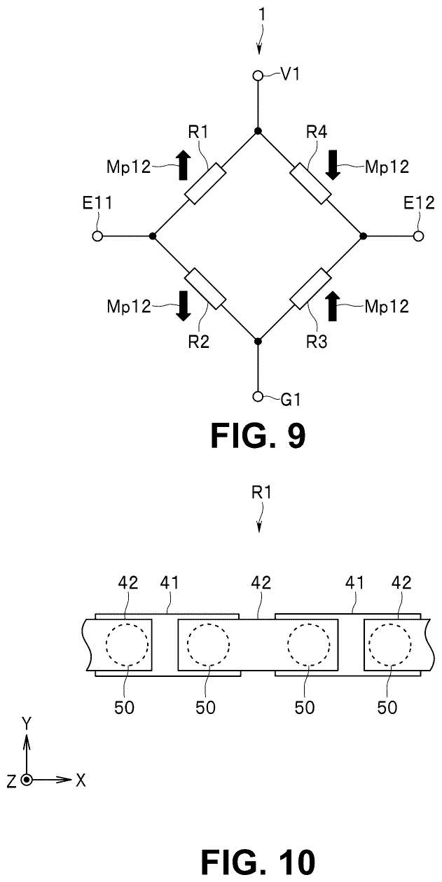

FIG. 8 is a plan view showing a magnetic sensor according to an example embodiment of the disclosure. FIG. 9 is a circuit diagram showing a circuit configuration of the magnetic sensor according to the example embodiment of the disclosure. FIG. 10 is a plan view showing a part of the magnetic sensor according to the example embodiment of the disclosure. The definitions of the X direction, the Y direction, and the Z direction shown in FIG. 8 and FIG. 10 are the same as those in FIG. 1.

The magnetic sensor 1 according to the example embodiment is configured to detect an external magnetic field MF including a perpendicular component and generate at least one detection signal. The magnetic sensor 1 includes a power supply port V1, a ground port G1, a first output port E11, a second output port E12, a first resistor section R1, a second resistor section R2, a third resistor section R3, a fourth resistor section R4, and a substrate 10. The first to fourth resistor sections R1 to R4 and a plurality of respective terminals corresponding to the power supply port V1, the ground port G1, and the first and second output ports E11 and E12 are provided on the substrate 10.

Each of the first to fourth resistor sections R1 to R4 includes a plurality of MR elements 50 and is configured to detect the external magnetic field MF to generate at least one detection signal. Since each of the first to fourth resistor sections R1 to R4 includes the plurality of MR elements 50, it can be said that the magnetic sensor 1 includes the plurality of MR elements 50.

As shown in FIG. 9, the first resistor section R1 is provided between the power supply port V1 and the first output port E11 in the circuit configuration. The second resistor section R2 is provided between the ground port G1 and the first output port E11 in the circuit configuration. The third resistor section R3 is provided between the ground port G1 and the second output port E12 in the circuit configuration. The fourth resistor section R4 is provided between the power supply port V1 and the second output port E12 in the circuit configuration. Note that, in the application, the expression “in the (a) circuit configuration” is used to indicate a layout in a circuit diagram, not a layout in a physical configuration.

A voltage or a current having given specific magnitude is applied to the power supply port V1. The ground port G1 is connected to the ground.

FIG. 8 shows an example of the layout of the first to fourth resistor sections R1 to R4. In this example, the first and second resistor sections R1 and R2 are arranged in a direction parallel to the X direction. The second resistor section R2 is arranged forward of the first resistor section R1 in the X direction.

The third and fourth resistor sections R3 and R4 are arranged in the direction parallel to the X direction. The fourth resistor section R4 is arranged forward of the third resistor section R3 in the −X direction. The third resistor section R3 is arranged forward of the second resistor section R2 in the −Y direction. The fourth resistor section R4 is arranged forward of the first resistor section R1 in the −Y direction.

Note that the layout of the first to fourth resistor sections R1 to R4 is not limited to the example shown in FIG. 8. For example, the first to fourth resistor sections R1 to R4 may be arranged in a given specific order in the direction parallel to the X direction or in a direction parallel to the Y direction.

Next, a concrete configuration of the magnetic sensor 1 will be described in detail with reference to FIG. 10. Each of the first to fourth resistor sections R1 to R4 further includes a plurality of lower electrodes 41 and a plurality of upper electrodes 42. Note that FIG. 10 illustrates a part of the first resistor section R1. The plurality of lower electrodes 41 are arranged on the substrate 10 (refer to FIG. 8). The plurality of MR elements 50 are arranged on the plurality of lower electrodes 41. The plurality of upper electrodes 42 are arranged on the plurality of MR elements 50. The plurality of lower electrodes 41 and the plurality of upper electrodes 42 are formed of a conductive material such as Cu, for example.

The plurality of MR elements 50 may be connected in series to each other by the plurality of lower electrodes 41 and the plurality of upper electrodes 42. In this case, a method of connecting the plurality of MR elements 50 is as follows. As shown in FIG. 10, each of the lower electrodes 41 has an elongated shape. Every two lower electrodes 41 that are adjacent to each other in the longitudinal direction of the lower electrodes 41 have a gap therebetween. Each MR element 50 is arranged in the vicinity of each of both longitudinal ends on the upper surface of the corresponding lower electrode 41. Each upper electrode 42 has an elongated shape, and electrically connects the two adjacent MR elements 50 arranged on two lower electrodes 41 that are adjacent to each other in the longitudinal direction of the lower electrodes 41. In such a manner, the plurality of MR elements 50 are connected in series.

Next, with reference to FIG. 9, the magnetization direction of the first magnetic layer (magnetization pinned layer) 52 in each of the first to fourth resistor sections R1 to R4 will be described. In FIG. 9, the magnetization direction Mp12 of the first magnetic layer (fixed magnetic layer) 52 in each of the resistor sections R1 to R4 is indicated by an arrow. Since the magnetization direction Mp12 of the inner magnetic layer 523 of the first magnetic layer 52 contributes to the change in resistance with respect to the magnetization direction Mf1 of the second magnetic layer 54, only the magnetization direction Mp12 of the inner magnetic layer 523 is shown in FIG. 9. As shown in FIG. 9, the magnetization direction Mp12 of the first magnetic layer 52 of each of the plurality of MR elements 50 in the first resistor section R1 and the third resistor section R3 includes a component in the same direction, and the magnetization direction Mp12 of the first magnetic layer 52 of each of the plurality of MR elements 50 in the second resistor section R2 and the fourth resistor section R4 includes a component in the same direction and is adjusted to be opposite to that of each of the first resistor section and the third resistor section R1 and R3. As shown in FIG. 9, the magnetization direction Mp12 of the first magnetic layer 52 of each of the plurality of MR elements 50 in the first resistor section R1 and the third resistor section R3 is, for example, the Z direction, and the magnetization direction Mp12 of the first magnetic layer 52 of each of the plurality of MR elements 50 in the second resistor section R2 and the fourth resistor section R4 is the −Z direction.

Next, with reference to FIG. 9, at least one detection signal generated by the magnetic sensor 1 is described. When the direction of the external magnetic field MF is the Z direction, the resistance of each of the plurality of MR elements 50 of the first resistor section R1 and the third resistor section R3 is reduced, and the resistance of each of the plurality of MR elements 50 of the second resistor section R2 and the fourth resistor section R4 is increased. As a result, the resistance of each of the first and third resistor sections R1 and R3 is reduced, and the resistance of each of the second and fourth resistor sections R2 and R4 is increased.

When the direction of the external magnetic field MF is the −Z direction, a change in resistance of the first to fourth resistor sections R1 to R4 is reversed to that of a case where the direction of the external magnetic field MF is the Z direction above.

As described above, when the direction and the magnitude of the external magnetic field MF change, the resistance of each of the first to fourth resistor sections R1 to R4 changes so that the resistance of each of the first and third resistor sections R1 and R3 is increased while the resistance of each of the second and fourth resistor sections R2 and R4 is reduced, or the resistance of each of the first and third resistor sections R1 and R3 is reduced while the resistance of each of the second and fourth resistor sections R2 and R4 is increased. With this, the potential of a connection point between the first and second resistor sections R1 and R2, i.e., the potential of the first output port E11, and the potential of a connection point between the third and fourth resistor sections R3 and R4, i.e., the potential of the second output port E12, change. The magnetic sensor 1 may generate a signal corresponding to the potential of the first output port E11 and a signal corresponding to the potential of the second output port E12, as respective detection signals. Alternatively, the magnetic sensor 1 may generate a signal corresponding to a potential difference between the first output port E11 and the second output port E12, as a detection signal. In this case, the magnetic sensor 1 may further include a differential amplifier (differential detector) that outputs a signal corresponding to the potential difference between the first output port E11 and the second output port E12, as a detection signal.

As described above, in the magnetic sensor 1, when the plurality of MR elements 50 are formed to form a bridge circuit, the MR elements 50 in each of which the exchange bias magnetic field is generated so that the magnetization direction of the first magnetic layer 52 is fixed in one direction of the perpendicular directions and the MR elements 50 in each of which the exchange bias magnetic field is generated so that the magnetization direction of the first magnetic layer 52 is fixed in the direction opposite to the one direction of the perpendicular directions are formed on the substrate 10. Then, a change in the external magnetic field MF in the perpendicular direction is detected by a change in resistance of each MR element 50, and is output as a detection signal such as a voltage by the bridge circuit shown in FIG. 9.

As already described, in the MR element 50 of the disclosure, the magnitude of the exchange bias magnetic field generated between the antiferromagnetic layer 51 and the specific metal layer 5211 can be increased. The perpendicular magnetic anisotropy energy of the outer magnetic layer 521 is smaller than the perpendicular magnetic anisotropy energy of the inner magnetic layer 523. In other words, the perpendicular magnetic anisotropy energy of the inner magnetic layer 523 is greater than the perpendicular magnetic anisotropy energy of the outer magnetic layer 521. These magnetic actions can return the magnetization direction of the first magnetic layer 52 to the original perpendicular direction in the course of bringing the external magnetic field MF in the zero magnetic field. Hence, in the magnetic sensor 1 in which the plurality of MR elements 50 are arranged, the magnetization direction of the first magnetic layer 52 can be always kept in one direction of the perpendicular directions in the zero magnetic field, and a stable output can be obtained. In particular, in each MR element 50 of the disclosure, the first magnetic layer 52 has the SAF structure, and the magnitude of the exchange bias magnetic field generated between the antiferromagnetic layer 51 and the first magnetic layer 52 is increased, so that the magnetization of the first magnetic layer 52 in the zero magnetic field state can be more effectively and stably fixed in one direction of the perpendicular directions. Hence, in the magnetic sensor 1 including the MR elements 50 in each of which the first magnetic layer 52 has the SAF structure and the magnitude of the exchange bias magnetic field generated between the antiferromagnetic layer 51 and the first magnetic layer 52 is increased, stable output can be obtained more effectively.

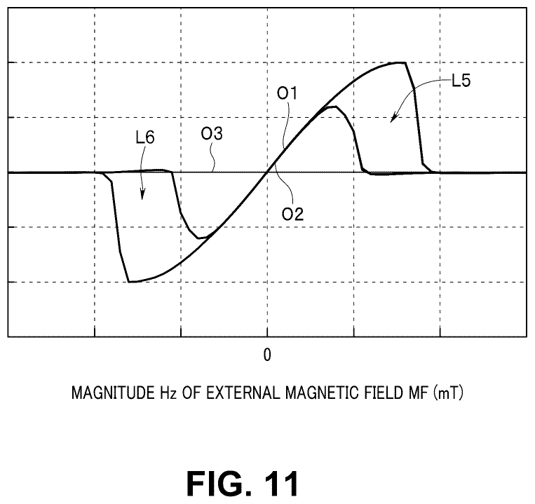

FIG. 11 is an output diagram of a half-bridge circuit of the magnetic sensor 1 according to the example embodiment of the disclosure. In FIG. 11, the horizontal axis represents the external magnetic field MF, and the vertical axis represents the output (voltage value). As in FIG. 3, the external magnetic field MF represented in the horizontal axis is defined as a positive external magnetic field when the external magnetic field MF is applied in the Z direction shown in FIG. 1, and as a negative external magnetic field when the external magnetic field MF is applied in the −Z direction from the zero magnetic field. As shown in FIG. 11, when a positive external magnetic field MF is applied from the zero magnetic field, reaches a given specific external magnetic field MF, and exceeds the reverse magnetic field of the inner magnetic layer 523, the magnetization direction Mp12 of the inner magnetic layer 523 of each of the two resistor sections R1 and R2 (for example, the resistor sections R1 and R2 in FIG. 9) in the half bridge is oriented in the same direction as the external magnetic field MF, which results in no potential difference to thereby enter a state where no change in output occurs. Thereafter, when the external magnetic field MF is reduced, the magnetization direction Mp12 of the inner magnetic layer 523 returns to the original state so as to approach the zero magnetic field, and the output also returns. A hysteresis loop L5 is obtained by the process above. This similarly applies when a negative external magnetic field MF is applied from the zero magnetic field. Specifically, when the negative external magnetic field MF is applied from the zero magnetic field, reaches a given specific external magnetic field MF, and exceeds the reverse magnetic field of the inner magnetic layer 523, the magnetization direction Mp12 of the inner magnetic layer 523 of each of the two resistance sections R1 and R2 in the half bridge is oriented in the same direction as that of the external magnetic field MF, which results in no potential difference to thereby enter a state where no change in output occurs. Thereafter, when the external magnetic field MF is reduced, the magnetization direction Mp12 of the inner magnetic layer 523 returns to the original state so as to approach the zero magnetic field, and the output also returns. A hysteresis loop L6 is obtained by the process above. As shown in FIG. 11, output curves O1 and O2 each have a finite (not zero) inclination, and the inclinations of the two output curves O1 and O2 are equal. This is because an exchange bias magnetic field having sufficient magnitude is generated between the first magnetic layer 52 and the antiferromagnetic layer 51 in the MR element 50 of the disclosure. Here, the inclinations of the output curves O1 and O2 can be obtained by dividing the output difference between the magnitudes Hz of the external magnetic field MF at two points by the width between the magnitudes Hz of the external magnetic field at the two points, the two points being obtained by shifting from the zero magnetic field toward the positive side and from the zero magnetic field toward the negative side by 10% each of 20% of the width of the external magnetic field MF between the hysteresis loops L5 and L6. When the difference in inclination between the output curves O1 and O2 (the absolute value of the inclination of the output curve O1/inclination of the output curve O2−1) is 5% or less, the output curves may be regarded as being equal.

In contrast, in the magnetic sensors using the MR elements of the comparative example having the magnetization curves in FIG. 5, when the magnetization direction Mp12 of the inner magnetic layers 523 of each of the two resistor sections R1 and R2 in the half bridge exceeds the reverse magnetic field of the inner magnetic layer 523 and is oriented in the same direction as that of the external magnetic field MF, the magnetization direction Mp12 of the inner magnetic layer 523 of each of the two resistor sections do not return to an antiparallel state even when the external magnetic field MF is reduced thereafter. Hence, in the comparative example, it is estimated that an output curve O3 maintains the output at the time of the zero magnetic field, in other words, enters in a state with substantially no output.

As described above, the magnetic sensor 1 of the disclosure can provide stable output in the range of the external magnetic field MF in which the magnetization direction Mf1 of each second magnetic layer changes in one direction of the perpendicular directions and the opposite direction thereof.

Note that the disclosure is not limited to each of the foregoing example embodiments, and various modifications may be made thereto. For example, the specific metal layer 5211 may be formed of a material other than the ferromagnetic material containing Co and Fe, or may be formed of a ferromagnetic material containing Co, Fe, and another element. For the crystal structures at the contact surface between the antiferromagnetic layer 51 and the specific metal layer 5211 and the third metal layers 5235 and 5236 in contact with the spacer layer 53, crystal structures and compositions other than those described above may be selected.

The metal layers 5215 and 5231 in contact with the nonmagnetic layer 522 above and below thereof may be formed of, for example, CoFe. Thereby, RKKY exchange coupling via the nonmagnetic layer 522 can be strengthened, and the sensing range can be widened. In this case, when the specific metal layer 5211 in contact with the antiferromagnetic layer 51 is formed of CoFe, the specific metal layer 5211 contains a larger amount of Fe than that of each of the metal layers 5215 and 5231. As an example, the specific metal layer 5211 is formed with Co_{70 at %} Fe_{30 at %}, and the metal layers 5215 and 5231 are formed with Co_{90 at %}Fe_{10 at %}.

As described above, a magnetoresistive element according to one embodiment of the disclosure is a magnetoresistive element configured to have a resistance that changes according to an external magnetic field, and includes a first magnetic layer, a second magnetic layer whose magnetization direction changes according to an external magnetic field, a spacer layer arranged between the first magnetic layer and the second magnetic layer, and an antiferromagnetic layer arranged on a side of the first magnetic layer opposite to the spacer layer. The first magnetic layer is magnetized to include a component in a perpendicular direction orthogonal to an in-plane direction. The first magnetic layer includes a stack structure in which a stack of a first metal layer and a second metal layer stacked together is repeatedly stacked. The first metal layer in each stack is arranged on a side closer to the antiferromagnetic layer than the second metal layer is. A specific metal layer of the first metal layers that is in contact with the antiferromagnetic layer is formed with a composition different from a composition of another metal layer that is not in contact with the antiferromagnetic layer.

In the magnetoresistive element according to one embodiment of the disclosure, the first magnetic layer may include an inner magnetic layer, an outer magnetic layer, and a nonmagnetic layer arranged between the inner magnetic layer and the outer magnetic layer. The inner magnetic layer is arranged on a side farther from the antiferromagnetic layer than the outer magnetic layer is. The inner magnetic layer and the outer magnetic layer may be magnetized so as to include respective components in opposite directions in the perpendicular directions.

In the magnetoresistive element according to one embodiment of the disclosure, the outer magnetic layer may include a stack structure in which a stack is repeatedly stacked.

In the magnetoresistive element according to one embodiment of the disclosure, the first magnetic layer may include a third metal layer in contact with the spacer layer. The third metal layer may be formed of a different composition from those of the first metal layer and the second metal layer.

In the magnetoresistive element according to one embodiment of the disclosure, in a magnetization curve of a structure including the first magnetic layer and the antiferromagnetic layer, a first hysteresis loop obtained by applying the external magnetic field in one direction of the perpendicular directions from a zero magnetic field and a second hysteresis loop obtained by applying the external magnetic field in a direction opposite to the one direction from the zero magnetic field may appear asymmetrically with respect to a magnetization point of the zero magnetic field as a center of point symmetry.

In the magnetoresistive element according to one embodiment of the disclosure, magnetization curves during transition from a first hysteresis loop to a second hysteresis loop and during transition from the second hysteresis loop to the first hysteresis loop may overlap each other.

In the magnetoresistive element according to one embodiment of the disclosure, the antiferromagnetic layer and the specific metal layer may have crystal structures different from each other at a contact surface between the antiferromagnetic layer and the specific metal layer.

In the magnetoresistive element according to one embodiment of the disclosure, the crystal structure of the antiferromagnetic layer at the contact surface may be a face-centered cubic lattice structure.

In the magnetoresistive element according to one embodiment of the disclosure, a crystal structure of the specific metal layer at the contact surface may be a body-centered cubic lattice structure.

In the magnetoresistive element according to one embodiment of the disclosure, the specific metal layer may contain Co and Fe.

In the magnetoresistive element according to one embodiment of the present disclosure, the composition of the specific metal layer may be represented by Co_{X}Fe_{100-X} (X is at %), where X may be 20 or more and 90 or less.

In the magnetoresistive element according to one embodiment of the disclosure, the other metal layer may be of Co.

In the magnetoresistive element according to one embodiment of the disclosure, the second metal layer may be of Pt or Pd.

In the magnetoresistive element according to one embodiment of the disclosure, the antiferromagnetic layer may be formed of IrMn or PtMn.

In the magnetoresistive element according to one embodiment of the disclosure, the specific metal layer may have a film thickness larger than a film thickness of the other metal layer.

In the magnetoresistive element according to one embodiment of the disclosure, the specific metal layer may have a film thickness of 6 Å or more and 20 Å or less, and the other metal layer may have a film thickness of 3 Å or more and 8 Å or less.

In the magnetoresistive element according to one embodiment of the disclosure, the magnitude of the exchange bias magnetic field generated between the specific metal layer and the antiferromagnetic layer may be greater than the magnitude of the exchange bias magnetic field generated when the other metal layer is in contact with the antiferromagnetic layer.

In the magnetoresistive element according to one embodiment of the disclosure, the perpendicular magnetic anisotropy energy of the outer magnetic layer may be smaller than the perpendicular magnetic anisotropy energy of the inner magnetic layer.

A magnetic sensor according to one embodiment of the disclosure includes a magnetoresistive element and is configured to detect an external magnetic field including a component in a perpendicular direction. The magnetoresistive element is the magnetoresistive element disclosed herein.

In the magnetic sensor according to one embodiment of the disclosure, an output curve may have a third hysteresis loop obtained by applying the external magnetic field in one direction of the perpendicular directions from a zero magnetic field and a fourth hysteresis loop obtained by applying the external magnetic field in a direction opposite to the one direction from the zero magnetic field, and inclination of the output curve during transition from the third hysteresis loop to the fourth hysteresis loop and inclination of the output curve during transition from the fourth hysteresis loop to the third hysteresis loop may be equal.

According to the disclosure, the magnetization stability of the first magnetic layer can be improved.

In addition to the magnetic sensor disclosed herein, the following clauses are disclosed below.

Clause 1. A magnetoresistive element (50) configured to have a resistance changing according to an external magnetic field (MF), the magnetoresistive element (50) including:
a first magnetic layer (52);
a second magnetic layer (54) whose magnetization direction (Mf1) changes according to the external magnetic field (MF);
a spacer layer (53) arranged between the first magnetic layer (52) and the second magnetic layer (54); and
an antiferromagnetic layer (51) arranged on a side of the first magnetic layer (52) opposite to the spacer layer (53), the first magnetic layer (52) being magnetized to include a component in a perpendicular direction orthogonal to an in-plane direction, the first magnetic layer (52) including a stack structure in which a stack (521A, 521B, 523A, 523B) of a first metal layer (5211, 5213, 5231, 5233) and a second metal layer (5212, 5214, 5232, 5234) stacked together is repeatedly stacked, the first metal layer (5211, 5213, 5231, 5233) in each stack (521A, 521B, 523A, 523B) being arranged on a side closer to the antiferromagnetic layer (51) than the second metal layer (5212, 5214, 5232, 5234) is, in which
a specific metal layer (5211) of the first metal layers (5211, 5213, 5231, 5233) that is in contact with the antiferromagnetic layer (51) is formed with a composition different from a composition of another metal layer (5213, 5231, 5233) that is not in contact with the antiferromagnetic layer (51).

Clause 2. The magnetoresistive element (50) according to clause 1, in which
the first magnetic layer (52) includes an inner magnetic layer (523), an outer magnetic layer (521), and a nonmagnetic layer (522) arranged between the inner magnetic layer (523) and the outer magnetic layer (521), the inner magnetic layer (523) being arranged on a side farther from the antiferromagnetic layer (51) than the outer magnetic layer (521) is, and
the inner magnetic layer (523) and the outer magnetic layer (521) are magnetized to include components in opposite directions in the perpendicular direction.

Clause 3. The magnetoresistive element (50) according to clause 2, in which the outer magnetic layer (521) includes the stack structure in which the stack (521A, 521B) is repeatedly stacked.

Clause 4. The magnetoresistive element (50) according to any of clauses 1 to 3, in which the first magnetic layer (52) includes a third metal layer (5236) in contact with the spacer layer (53), the third metal layer (5236) being formed with a composition different from compositions of the first metal layer (5211, 5213, 5231, 5233) and the second metal layer (5212, 5214, 5232, 5234).

Clause 5. The magnetoresistive element (50) according to any of clauses 1 to 4, in which in a magnetization curve of a structure including the first magnetic layer (52) and the antiferromagnetic layer (51), a first hysteresis loop (L1) obtained by applying the external magnetic field (MF) in one direction of the perpendicular direction from a zero magnetic field and a second hysteresis loop (L2) obtained by applying the external magnetic field (MF) in a direction opposite to the one direction from the zero magnetic field appear asymmetrically with respect to a magnetization point (m) of the zero magnetic field as a center of point symmetry.

Clause 6. The magnetoresistive element (50) according to clause 5, in which a magnetization curve (MC1) during transition from the first hysteresis loop (L1) to the second hysteresis loop (L2) and a magnetization curve (MC2) during transition from the second hysteresis loop (L2) to the first hysteresis loop (L1) overlap each other.

Clause 7. The magnetoresistive element (50) according to any of clauses 1 to 6, in which the antiferromagnetic layer (51) and the specific metal layer (5211) have crystal structures different from each other at a contact surface between the antiferromagnetic layer (51) and the specific metal layer (5211).

Clause 8. The magnetoresistive element (50) according to clause 7, in which the antiferromagnetic layer (51) has a face-centered cubic lattice structure as the crystal structure at the contact surface.

Clause 9. The magnetoresistive element (50) according to clause 7 or 8, in which the specific metal layer (5211) has a face-centered cubic lattice structure as the crystal structure at the contact surface.

Clause 10. The magnetoresistive element (50) according to any of clauses 1 to 9, in which the specific metal layer (5211) contains Co and Fe.

Clause 11. The magnetoresistive element (50) according to clause 10, in which the specific metal layer (5211) has a composition expressed as Co_{X}Fe_{100-X} (X is at %), X being 20 or more and 90 or less.

Clause 12. The magnetoresistive element (50) according to clause 10 or 11, in which the other metal layer (5213, 5231, 5233) is of Co.

Clause 13. The magnetoresistive element (50) according to any of clauses 10 to 12, in which the second metal layer (5212, 5214, 5232, 5234) is of Pt or Pd. Clause 14. The magnetoresistive element (50) according to any of clauses 10 to 13, in which the antiferromagnetic layer (51) is formed of IrMn or PtMn.

Clause 15. The magnetoresistive element (50) according to any of clauses 1 to 14, in which the specific metal layer (5211) has a film thickness larger than a film thickness of the other metal layer (5213, 5231, 5233).

Clause 16. The magnetoresistive element (50) according to any of clauses 1 to 15, in which the film thickness of the specific metal layer (5211) is 6 Å or more and 20 Å or less, and the film thickness of the other metal layer (5213, 5231, 5233) is 3 Å or more and 8 Å or less.

Clause 17. The magnetoresistive element (50) according to any of clauses 1 to 16, in which magnitude of an exchange bias magnetic field generated between the specific metal layer (5211) and the antiferromagnetic layer (51) is larger than magnitude of an exchange bias magnetic field generated when the other metal layer (5213, 5231, 5233) is in contact with the antiferromagnetic layer (51).

Clause 18. The magnetoresistive element (50) according to clause 2 or 3, in which perpendicular magnetic anisotropy energy of the outer magnetic layer (521) is smaller than perpendicular magnetic anisotropy energy of the inner magnetic layer (523).

Clause 19. A magnetic sensor (1) including
the magnetoresistive element (50) according to any of clauses 1 to 18, in which
the magnetic sensor (1) is configured to detect the external magnetic field (MF) including the component in the perpendicular direction.

Clause 20. The magnetic sensor (1) according to clause 19, in which an output curve (O1, O2) has a third hysteresis loop (L5) obtained by applying the external magnetic field (MF) in one direction of the perpendicular direction from a zero magnetic field and a fourth hysteresis loop (L6) obtained by applying the external magnetic field (MF) in a direction opposite to the one direction from the zero magnetic field, inclination of an output curve (O1, O2) during transition from the third hysteresis loop (L5) to the fourth hysteresis loop (L6) and inclination of an output curve (O1, O2) during transition from the fourth hysteresis loop (L6) to the third hysteresis loop (L5) are equal.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A magnetoresistive element comprising:
a first magnetic layer magnetized in a direction having a component perpendicular to an in-plane direction;
a second magnetic layer having a magnetization direction variable in response to an external magnetic field;
a spacer layer disposed between the first magnetic layer and the second magnetic layer; and
an antiferromagnetic layer disposed on a side of the first magnetic layer opposite to the spacer layer, wherein
the first magnetic layer includes a multilayer structure including a plurality of unit laminates being stacked,
each of the plurality of unit laminates includes a first metal layer and a second metal layer,
in each of the plurality of unit laminates, the first metal layer is disposed closer to the antiferromagnetic layer than the second metal layer,
the first metal layer included in one of the plurality of unit laminates that is closest to the antiferromagnetic layer is a specific metal layer which is in contact with the antiferromagnetic layer,
the first metal layer included in each of the unit laminates other than the one of the plurality of unit laminate closest to the antiferromagnetic layer is an other metal layer which is not in contact with the antiferromagnetic layer, and
the specific metal layer includes a material different from a material of the other metal layer.

2. The magnetoresistive element according to claim 1, wherein
the first magnetic layer includes an inner magnetic layer, an outer magnetic layer, and a nonmagnetic layer disposed between the inner magnetic layer and the outer magnetic layer, wherein
the inner magnetic layer is disposed on a side farther from the antiferromagnetic layer than the outer magnetic layer is, and
the inner magnetic layer and the outer magnetic layer are magnetized in directions having components opposite to each other in a direction perpendicular to the in-plane direction.

3. The magnetoresistive element according to claim 2, wherein the outer magnetic layer includes the multilayer structure in which each of the plurality of unit laminates is repeatedly stacked.

4. The magnetoresistive element according to claim 1, wherein
the first magnetic layer includes a third metal layer in contact with the spacer layer, and
the third metal layer is formed of a material different from a material of the first metal layer and the second metal layer included in the plurality of unit laminates.

5. The magnetoresistive element according to claim 1, wherein,
in a magnetization curve of the first magnetic layer, a first hysteresis loop obtained by applying the external magnetic field from a zero magnetic field in one direction perpendicular to the in-plane direction and a second hysteresis loop obtained by applying the external magnetic field from the zero magnetic field in a direction opposite to the one direction are asymmetric with respect to a magnetization point at the zero magnetic field as a center of point symmetry.

6. The magnetoresistive element according to claim 5, wherein a magnetization curve during transition from the first hysteresis loop to the second hysteresis loop and a magnetization curve during transition from the second hysteresis loop to the first hysteresis loop overlap each other.

7. The magnetoresistive element according to claim 1,
wherein a crystal structure of the antiferromagnetic layer and a crystal structure of the specific metal layer are different from each other at a contact surface between the antiferromagnetic layer and the specific metal layer.

8. The magnetoresistive element according to claim 7, wherein the antiferromagnetic layer has a face-centered cubic lattice structure as the crystal structure at the contact surface.

9. The magnetoresistive element according to claim 7, wherein the specific metal layer has a body-centered cubic lattice structure as the crystal structure at the contact surface.

10. The magnetoresistive element according to claim 1, wherein the specific metal layer includes Co and Fe.

11. The magnetoresistive element according to claim 10,
wherein a composition of the specific metal layer is represented by Co_{X}Fe_{100-X} where x is in atomic percent, and x is in a range of 20 to 90.

12. The magnetoresistive element according to claim 10, wherein the other metal layer is Co.

13. The magnetoresistive element according to claim 10, wherein the second metal layer is Pt or Pd.

14. The magnetoresistive element according to claim 10, wherein the antiferromagnetic layer includes IrMn or PtMn.

15. The magnetoresistive element according to claim 1, wherein the specific metal layer has a film thickness larger than a film thickness of the other metal layer.

16. The magnetoresistive element according to claim 1, wherein the film thickness of the specific metal layer is 6 Å or more and 20 Å or less, and the film thickness of the other metal layer is 3 Å or more and 8 Å or less.

17. The magnetoresistive element according to claim 1, wherein magnitude of an exchange bias magnetic field generated between the specific metal layer and the antiferromagnetic layer is greater than magnitude of an exchange bias magnetic field generated when the other metal layer is in contact with the antiferromagnetic layer.

18. The magnetoresistive element according to claim 2, wherein perpendicular magnetic anisotropy energy of the outer magnetic layer is smaller than perpendicular magnetic anisotropy energy of the inner magnetic layer.

19. A magnetic sensor comprising
the magnetoresistive element according to claim 1, wherein
the magnetic sensor is configured to detect the external magnetic field including the component in the perpendicular direction.

20. The magnetic sensor according to claim 19, wherein
an output curve of the magnetic sensor includes a third hysteresis loop obtained by applying the external magnetic field from a zero magnetic field in one direction perpendicular to the in-plane direction and a fourth hysteresis loop obtained by applying the external magnetic field from the zero magnetic field in a direction opposite to the one direction, and
a slope of the output curve during a transition from the third hysteresis loop to the fourth hysteresis loop is equivalent to a slope of the output curve during a transition from the fourth hysteresis loop to the third hysteresis loop.
